(19) United States
(12) Patent Application Publication
(10) Pub. No.: US 2024/0038580 A1
(43) Pub. Date: Feb. 1, 2024

(54) LOCOS OR SIBLK TO PROTECT DEEP TRENCH POLYSILICON IN DEEP TRENCH AFTER STI PROCESS

(71) Applicant: Texas Instruments Incorporated, Dallas, TX (US)

(72) Inventors: Hao Yang, Allen, TX (US); Asad Haider, Plano, TX (US); Guruvayurappan Mathur, Allen, TX (US); Abbas Ali, Plano, TX (US); Alexei Sadovnikov, Sunnyvale, CA (US); Umamaheswari Aghoram, Richardson, TX (US)

(21) Appl. No.: 17/877,976

(22) Filed: Jul. 31, 2022

(51) Int. Cl. H01L 21/762; H01L 29/06

(52) U.S. Cl. CPC H01L 21/76229; H01L 29/0623

(57) ABSTRACT

An electronic device includes a semiconductor substrate and a semiconductor surface layer having a first conductivity type, the semiconductor surface layer over the semiconductor substrate and having a top surface, a buried layer having an opposite second conductivity type between the semiconductor surface layer and the semiconductor substrate, a dielectric isolation layer that extends over and into the semiconductor surface layer, a deep trench structure that extends through the dielectric isolation layer into the semiconductor surface layer, and a silicide blocking layer on a top surface of the deep trench structure.

### CROSS REFERENCE TO RELATED APPLICATIONS

This application is related to application Ser. No. ______, (Texas Instruments Docket No. T101506US01, “DIE SIZE REDUCTION AND DEEP TRENCH DENSITY INCREASE USING DEEP TRENCH ISOLATION AFTER SHALLOW TRENCH ISOLATION INTEGRATION, by Haider, et al.), filed on even date herewith and incorporated herein by reference in its entirety.

### BACKGROUND

Isolation structures separate electrically circuits of different power supply domains and/or types, such as high and low voltage circuits or analog and digital circuits in an integrated circuit. Shallow trench isolation (STI) is a type of isolation structure with dielectric material deposited into shallow trenches etched between circuit areas to be laterally isolated. Deep trench isolation (DTI) is used to mitigate electric current leakage between adjacent semiconductor device components and other deep trench structures can be used for top side contacts (TSC).

### SUMMARY

In one aspect, an electronic device includes a semiconductor substrate and a semiconductor surface layer having a first conductivity type, the semiconductor surface layer over the semiconductor substrate and having a top surface, a buried layer having an opposite second conductivity type between the semiconductor surface layer and the semiconductor substrate, a dielectric isolation layer that extends over and into the semiconductor surface layer, a deep trench structure that extends through the dielectric isolation layer into the semiconductor surface layer, and a silicide blocking layer on a top surface of the deep trench structure.

In another aspect, an integrated circuit includes a semiconductor surface layer over a semiconductor substrate, a dielectric isolation structure that extends into the semiconductor surface layer, a trench through the dielectric isolation structure and within the semiconductor surface layer, a first dielectric liner within the trench located directly on the semiconductor surface layer, a second dielectric liner within the trench located directly on the first dielectric liner, and a silicide blocking layer located over and touching the dielectric isolation structure and the second dielectric liner.

In a further aspect, A method of fabricating an electronic device includes forming a dielectric isolation layer that extends over a semiconductor surface layer, forming a deep trench structure through the dielectric isolation layer, through the semiconductor surface layer, and into a buried layer, forming a silicide blocking layer on a first portion of the deep trench structure, and forming metal silicide on a second portion of the deep trench structure.

### BRIEF DESCRIPTION OF THE DRAWINGS

FIG. 1 is a partial sectional side elevation view of an electronic device that includes narrow and wide deep trench structures formed through shallow trench isolation with selective silicide block layers to mitigate unwanted silicidation.

FIG. 1A is a sectional side elevation view of the electronic device of FIG. 1 including a package structure.

FIGS. 1B and 1C show detail views of portions of FIG. 1.

FIG. 2 is a flow diagram of a method for making an electronic device and for making a deep trench structure in an electronic device.

FIGS. 3-35 are partial sectional side elevation views of the electronic device of FIG. 1 at various stages of fabrication according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating.

Deep trench structures that extend through STI structure may have polysilicon that can be silicided during transistor contact formation. Silicidation at the edges of wide deep trench structures can cause non-planar surface at the interface between deep trench liner oxide and the polysilicon used to form a contact to the buried layer and/or the substrate. Moreover, narrow deep trench structures may need to be isolated or floating for proper circuit operation, and narrow deep trench polysilicon can be exposed to undesired silicidation during transistor contact formation.

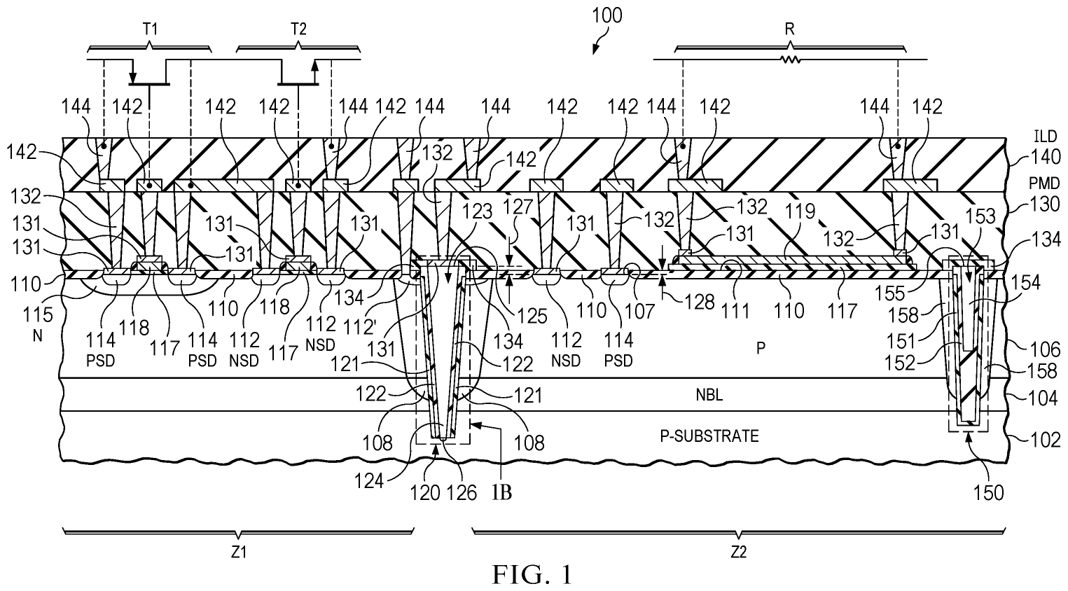

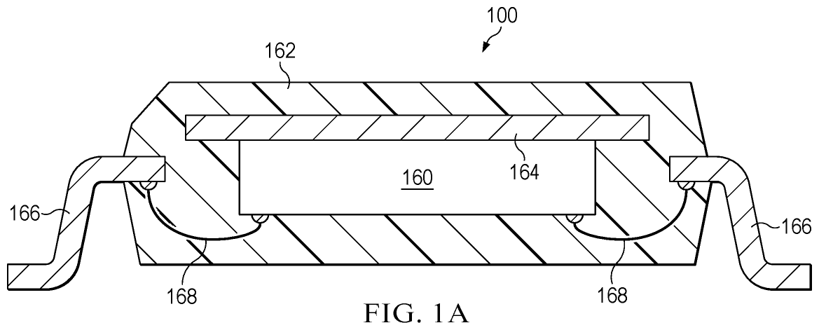

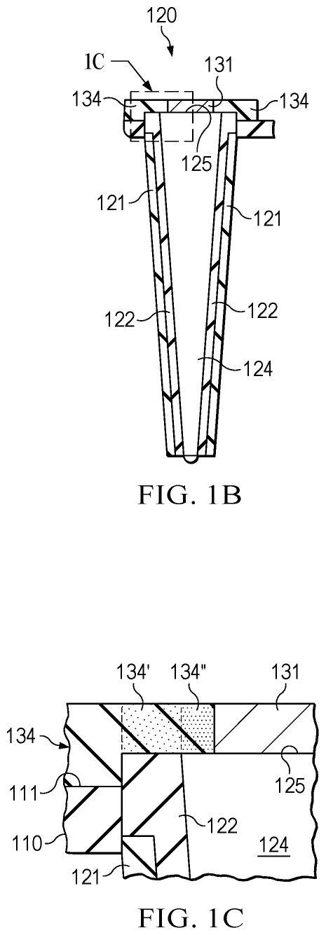

FIGS. 1 and 1A-1C show an electronic device 100 that includes a deep trench structure formed through a shallow trench isolation (STI) layer. As used herein the term “shallow trench isolation” refers to an oxide or other electrically insulating material (e.g., having a thickness in nm or greater) that is deposited or otherwise formed in a trench in a semiconductor surface layer for shallow trench isolation. The deep trench structure can be a deep trench isolation structure (DTI), or a top side contact (TSC) structure or implementations can include both DTI and TSC structures. The use of a shallow trench isolation structure provides benefits including providing or enhancing isolation around a deep trench structure. The deep trench structure facilitates electrical isolation between components or circuits, such as narrow DTI structures, and/or facilitates top side electrical connection to a device substrate using a wider TSC deep trench structure. The described examples include deep trench structures formed after the STI structures, with deep doped regions formed after STI processing to mitigate lateral diffusion of deep dopants and facilitate reduced lateral extent of the deep trench structure and deep doped regions and allow closer spacing transistors, resistors and other component structures in a semiconductor die. This benefit facilitates increased circuit density and/or reduced device size for improved electronic devices. The electronic device 100 in FIGS. 1 and 1A includes a deep trench structure formed through an STI structure, with a top side of the deep trench structure extending above a top side of the STI structure, and with a deep doped region surrounding a portion of the deep trench structure and having a lateral extent that is unaffected by the creation of the STI structure. The decoupling of the deep doped region lateral size facilitates advanced designs with reduced circuit size and/or increased circuit density. The electronic device 100 includes STI structures formed before the deep trench structures and before the deep doped region that at least partially surrounds the deep trench structure.

The electronic device 100 in one example is an integrated circuit product, only a portion of which is shown in FIG. 1. The electronic device 100 includes electronic components, such as transistors, resistors, capacitors fabricated on or in a semiconductor structure of a starting wafer, which is subsequently separated or singulated into individual semiconductor dies that are separately packaged to produce integrated circuit products. The electronic device 100 includes a semiconductor structure having a semiconductor substrate 102 (e.g., labeled “P-SUBSTRATE” in FIG. 1) and a buried layer 104 (e.g., labeled “NBL”) in a portion of the semiconductor substrate 102. The electronic device 100 also includes a semiconductor surface layer 106 (e.g., labeled “P”) with an upper or top side 107, as well as a deep doped region 108. In some examples the semiconductor surface layer 106 is an epitaxial layer and may be in-situ doped with a P-type dopant such as boron.

The electronic device 100 includes a dielectric isolation layer 110 that includes portions that may be contiguous or noncontiguous. In the illustrated example the dielectric isolation layer 110 is implemented as contiguous or noncontiguous shallow trench isolation (STI) structures. Other examples may implement the dielectric isolation layer 110 using contiguous or noncontiguous local oxidation of silicon (LOCOS) structures. The following discussion refers to examples in which the dielectric isolation layer 110 is implemented with STI structures without implied limitation thereto, and may refer to the dielectric isolation layer 110 as STI structures 110.

The STI structures 110 have upper or top surfaces 111 and extend into trenches in corresponding portions of the top side 107 of the semiconductor surface layer 106. In one example, the STI structures 110 are or includes silicon dioxide (SiO₂). The semiconductor substrate 102 in one example is a silicon or silicon on insulator (SOI) structure that include majority carrier dopants of a first conductivity type. The buried layer 104 extends in a portion of the semiconductor substrate 102 and includes majority carrier dopants of an opposite second conductivity type. In the illustrated implementation, the first conductivity type is P, the second conductivity type is N, the semiconductor substrate 102 is labeled “P”, and the buried layer 104 is an N-type buried layer labeled “NBL” in the drawings. In another implementation (not shown), the first conductivity type is N, and the second conductivity type is P. The semiconductor substrate 102 in one example includes a base silicon or silicon-on-insulator (SOI) wafer with an epitaxial silicon layer formed thereon. In one example, the buried layer 104 is implanted into a top side of the starting silicon or SOI wafer, and the semiconductor surface layer 106 is an epitaxial silicon layer formed over the buried layer 104.

The semiconductor surface layer 106 in the illustrated example is or includes epitaxial silicon having majority carrier dopants of the first conductivity type and is labeled “P” in the drawings. The deep doped region 108 includes majority carrier dopants of the second conductivity type (e.g., a deep N region). The deep doped region 108 extends from the semiconductor surface layer 106 into the buried layer 104. In another example, the deep doped region 108 extends through the buried layer 104 and into the semiconductor substrate 102. In the illustrated example, the deep doped region 108 extends from the semiconductor surface layer 106 partially into the buried layer 104 and does not extend into the underlying semiconductor substrate 102.

A first implanted region 112 (e.g., a first portion) of the semiconductor surface layer 106 along the top side 107 includes majority carrier dopants of the second conductivity type and is labeled “NSD” in the drawings. A second portion or implanted region 114 of the semiconductor surface layer 106 along the top side 107 includes majority carrier dopants of the first conductivity type and is labeled “PSD” in the drawings. A third portion 116 (e.g., a third implanted region) of the semiconductor surface layer 106 within the deep doped region 108 along the top side 107 includes majority carrier dopants of the second conductivity type and is labeled “NSD” in the drawings. While the top side 107 is shown in the present example as the top surface of the second implanted region 114, for this purpose of this description and the claims the top side 107 includes the top surface of the semiconductor surface layer 106 and other implanted regions such as the first implanted region 112 and second implanted region 114.

The electronic device 100 includes a first field effect transistor (FET) T1, and a second FET T2 formed on and/or in the semiconductor surface layer 106. The first transistor T1 is a p-channel FET with p-doped source/drains formed by corresponding second implanted regions, or source/drain implanted regions 114, within an n-doped region 115 in an upper portion of the semiconductor surface layer 106. The second transistor T2 is an n-channel FET with corresponding first implanted regions, or source/drain implanted regions 112, forming source/drains of the transistor T2. The transistors T1 and T2 include corresponding gate oxide or gate dielectric structures 117 formed over channel regions between the source/drain implanted regions 112, 114, as well as polysilicon gate electrodes 118 extending on the corresponding gate dielectric structures 117 spaced apart and above the respective transistor channel regions. The electronic device 100 also includes a polysilicon resistor R, including a gate dielectric structure 117 formed over a portion of one of the STI structures 110, as well as a polysilicon resistor structure 119 formed above the gate dielectric structure 117 of the resistor R.

The electronic device 100 includes a wide first deep trench structure 120 (e.g., a DTI or TSC structure) that provides a top side electrical contact to the semiconductor substrate 102 between a first zone Z1 and a second zone Z2, as well as a second, narrower deep trench structure 150 (e.g., a deep trench isolation or DTI structure) that provides electrical isolation. Some aspects of the first deep trench structure 120 are shown in greater detail in FIGS. 1B and 1C. In the illustrated example, the first and second transistors T1 and T2 are formed in the first zone Z1, and the resistor R is formed in the second zone Z2. The deep trench structure 120 includes a first dielectric liner 121 on a sidewall of a trench 123, and a second dielectric liner 122 on the first dielectric liner 121. The first and second dielectric liners 121, 122 may be referred to together as a bilayer dielectric liner. In one example, the first dielectric liner 121 is or includes a thermally grown silicon dioxide (SiO₂) of any suitable stoichiometry and thickness, and the second dielectric liner 122 is or includes a deposited silicon oxide (SiOₓ) of any suitable stoichiometry and thickness. The first dielectric liner 121 may merge with the STI structure 110 abutting the deep trench structure 120, resulting in a continuous material layer as illustrated in FIG. 1C.

The deep doped region 108 surrounds the deep trench structure 120. In another implementation, a single layer dielectric liner (not shown) is formed along the trench sidewall. In another implementation, a multilayer dielectric liner (not shown) includes more than two dielectric layers along the trench sidewall. The trench 123 is filled with doped polysilicon 124. A top surface 125 of the deep trench structure 120 includes the topmost surface of the polysilicon 124 and the topmost surface of the second dielectric liner 122. (See FIG. 1C.) The top surface 125 may be, and in the current example is shown as being, higher than the top surface 111 of the STI structure 110. The doped polysilicon 124 may be referred to herein as a “core” or “first core”. The trench 123 extends through the semiconductor surface layer 106 to the semiconductor substrate 102. In this implementation, the deep trench structure 120 extends through the semiconductor surface layer 106, through opposite upper and lower sides of the buried layer 104 and into the underlying semiconductor substrate 102. In another implementation, the deep trench structure 120 extends into the buried layer 104 but does not extend into the underlying semiconductor substrate 102. An implanted contact 126 to the semiconductor substrate 102 under the trench 123 includes majority carrier dopants of the first conductivity type. The bilayer dielectric liner 121, 122 extends on the sidewall of the trench 123 from the semiconductor surface layer 106 on the sidewall of the trench 123 from the semiconductor surface layer 106 to the buried layer 104 and into the semiconductor substrate 102. The bilayer dielectric liner 121, 122 conductively isolates the polysilicon 124 from the semiconductor surface layer 106.

The polysilicon 124 includes majority carrier dopants of the first conductivity type. The polysilicon 124 extends on the dielectric liner 122 and fills the trench 123 to above the top side 107 of the semiconductor surface layer 106. In the example of FIG. 1, the trench 123, the dielectric liner 122, and the polysilicon 124 extend beyond the top side 107 of the semiconductor surface layer 106 through a portion of the STI structure 110. A portion (e.g., side) of the STI structure 110 contacts (e.g., touches) a portion of the deep trench structure 120. The top surface 125 of the deep trench structure 120 extends upward beyond the top side 107 of the semiconductor surface layer 106 by a first distance 127, and the top surface 111 of the STI structure 110 extends upward beyond the top side 107 of the semiconductor surface layer 106 by a second distance 128.

The deep trench structure 120 and a narrower deep trench structure 150 in the electronic device 100 of FIG. 1 are fabricated after formation (e.g., growth or deposition) of the STI structure 110, and the first distance 127 is greater than the second distance 128 in the electronic device 100 of FIG. 1 (e.g., the polysilicon 124 extends upward past and above the top surface 111 of the STI structure 110 in the configuration and orientation shown in FIG. 1). In one example, the deep trench structure 120 extends in two dimensions to laterally encircle or surround one or both of the zones Z1 and/or Z2, and the electronic device 100 can have any suitable number of isolated zones (not shown) surrounded by similar deep trench structures 120. The electronic device 100 can include any number of electronic circuit components, such as transistors (e.g., T1 and T2), resistors (e.g., resistor R), capacitors, diodes, etc. (not shown) interconnected to form electrical circuits in one or more isolated regions, and the circuits of two or more isolated regions can be interconnected, for example, through openings in the deep trench structure or structures and/or by metallization routing interconnections.

The electronic device 100 includes a multilevel metallization structure, a portion of which is shown in FIG. 1. The electronic device 100 includes a first dielectric layer 130 (e.g., a pre-metal dielectric layer labeled “PMD” in FIG. 1) that extends on or over the STI structures 110 and portions of the top side 107 of the semiconductor surface layer 106 and over the top of the deep trench structure 120. In one example, the first dielectric (PMD) layer 130 is or includes SiO₂. The PMD layer 130 includes conductive contacts 132 that extend through the PMD layer 130 to form electrical contacts to the respective source/drain implanted regions 112 and 114 of the semiconductor surface layer 106.

Select portions of the top sides of the transistor polysilicon gate, implanted source/drain implanted regions 112 and 114, and the polysilicon 124 of the wide deep trench structure 120 are silicided to form a metal silicide 131. The metal silicide 131 can include titanium silicide, cobalt silicide or other metal silicide (e.g., a refractory metal silicide). The PMD layer 130 also includes a conductive contact 132 that forms an electrical (ohmic) contact to the doped polysilicon 124 along the top surface 125 of the deep trench structure 120, as well as a separate, optional conductive contact 132 that forms an electrical contact to a first implanted region 112′ that encircles the top of the deep trench structure 120 in the deep doped region 108 as shown in FIG. 1. In one example, the conductive contacts 132 are or include tungsten.

A silicide blocking layer 134 (SiBLK) extends on a portion of the top surface 125 of the first deep trench structure 120. The silicide blocking layer 134 in one example is a nitrogen-containing dielectric material that may include silicon nitride (SiN) or silicon oxynitride (e.g., SiON) of any suitable stoichiometry and thickness. In other examples, the silicide blocking layer 134 is or includes silicon oxide (e.g., SiOₓ) of any suitable stoichiometry and thickness. The silicide blocking layer 134 in one example covers the dielectric liners 121 and 122 of the first deep trench structure 120, and covers a first portion of the polysilicon 124 along edges thereof, while exposing (i.e., not covering) a second portion of the polysilicon 124 of the first deep trench structure 120 as shown in FIG. 1C. With further reference to FIG. 1C, a first portion 134′ is directly over and touches the second dielectric liner 122, and a second portion 134″ is directly over and touches the polysilicon 124. The metal silicide 131 extends on the portion of the polysilicon 124 at the top surface 125 of the first DTI structure 120, and a respective conductive metal contact 132 contacts the metal silicide 131 on the portion of the polysilicon 124 of the deep trench structure 120. The contact 132 extends through the pre-metal dielectric layer 130 to the metal silicide 131 and the pre-metal dielectric layer 130 covers the silicide blocking layer 134.

The silicide blocking layer 134 can help mitigate or avoid unwanted silicidation at the edges of polysilicon 124 on wide deep trench structures such as the first structure 120 and reduce or eliminate non-planar surface features at the interface between deep trench liner oxide 121 and the polysilicon 124 used to form an electrical contact to the buried layer 104 and/or the substrate 102. Various disclosed devices and methods of the present disclosure may be beneficially applied for circuit isolation using STI and wide, electrically contacted deep trench structures and narrow, electrically isolated deep trench structures, such as the deep trench structures 120 and 150 in FIG. 1. While such examples may be expected to provide improvements in performance relative to baseline implementations, no particular result is a requirement unless explicitly recited in a particular claim.

The multilevel metallization structure in this example also includes a second (e.g., interlayer or interlevel) dielectric layer 140 (e.g., SiOₓ), which is labeled “ILD” in FIG. 1. The second dielectric layer 140 includes conductive routing structures 142, such as conductive metal traces or lines. In one example, the conductive routing structures 142 are or include copper or aluminum or aluminum or other conductive metal. The second dielectric layer 140 includes conductive vias 144 that are or include copper or aluminum or other conductive metal. In one example, the electronic device 100 includes one or more further metallization layers or levels (not shown).

The electronic device 100 also includes a narrow second deep trench structure 150 having a bilayer liner 151 and 152 along the bottom and sidewalls of a second trench 153. In one example, the first dielectric liner 151 is or includes a thermally grown silicon dioxide (SiO₂) of any suitable stoichiometry and thickness, and the second dielectric liner 152 is or includes a deposited silicon oxide (SiOₓof any suitable stoichiometry and thickness. The second deep trench structure 150 includes polysilicon 154 that may also be referred to herein as a core or “second core”. The second deep trench structure 150 is laterally narrower than the first deep trench structure 120. The polysilicon 154 in the second deep trench structure 150 can be electrically floating with respect to one or more circuits of the electronic device and/or the substrate 102. The second trench 153 in the example of FIG. 1 is filled with the polysilicon 154 with an upper or top surface 155. A portion of the second deep trench structure 150 is surrounded by a second deep doped region 158 having majority carriers of the N-type (e.g., phosphorous). The second deep trench structure 150 extends through a second portion of the STI structure 110, through the semiconductor surface layer 106, and into the buried layer 104. The top surface 155 of the second deep trench structure extends above the top surface 111 of the second portion of the associated STI structure 110 by the distance 127.

In addition, a second silicide blocking layer 134 extends on and covers the top surface 155 of the second deep trench structure 150, including covering the bilayer liner 151 and 152 and the polysilicon 154 along the top surface 155. The second silicide blocking layer 134 in one example is or includes silicon oxynitride (e.g., SiON) of any suitable stoichiometry and thickness. In another example, the second silicide blocking layer 134 is or includes silicon oxide (e.g., SiOₓ) of any suitable stoichiometry and thickness. The second silicide blocking layer 134 in one example prevents silicidation of the polysilicon 154 of the second deep trench structure 150 and facilitates electrically floating isolation during operation of the electronic device 100. Various disclosed devices and methods of the present disclosure may be beneficially applied for circuit isolation using STI and narrow or floating deep trench structures such as the deep trench structures 120 and 150 in FIG. 1. While such examples may be expected to provide improvements in performance relative to baseline implementations, no particular result is a requirement unless explicitly recited in a particular claim.

As further shown in FIG. 1A, the finished electronic device 100 includes a package structure having a semiconductor die 160 enclosed in a molded package 162. In the illustrated example, the semiconductor die 160 is mounted on a conductive metal die attach pad 164, and conductive bond pads of the die 160 are electrically coupled to respective leads 166 via conductive bond wires 168 to form electrical connections to external circuitry, for example, of a printed circuit board (PCB, not shown) to which the packaged electronic device 100 may be attached.

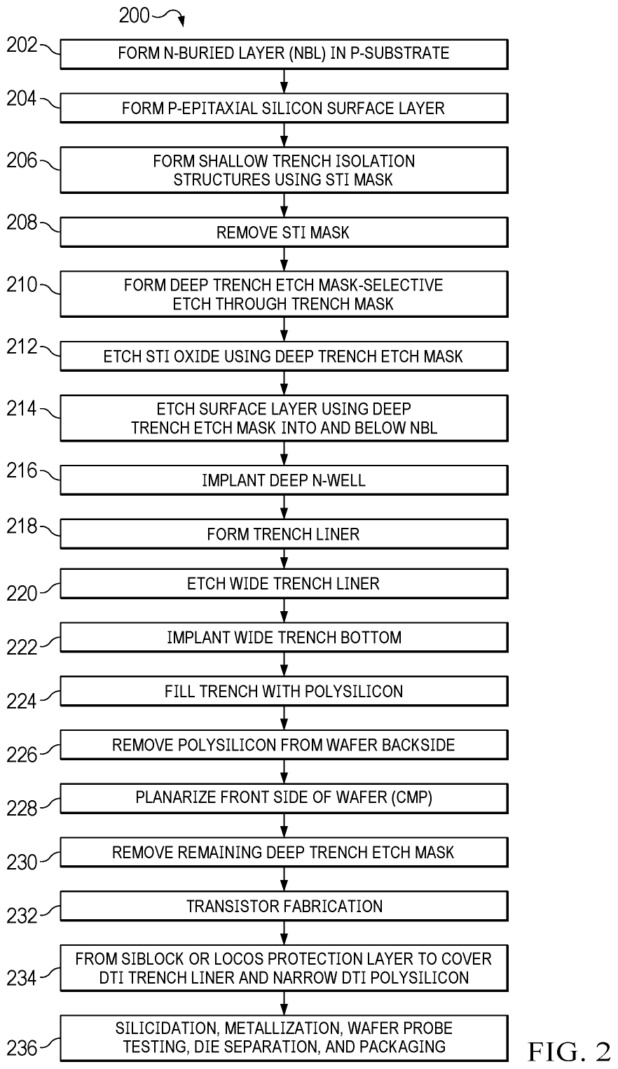

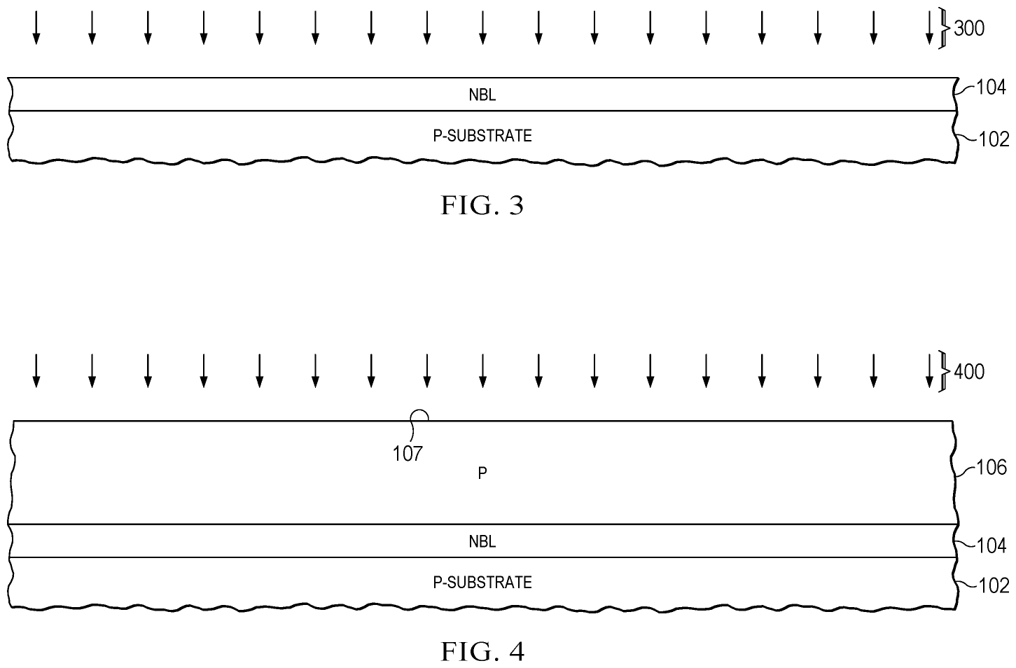

Referring also to FIGS. 2-35, FIG. 2 shows a method 200 for making an electronic device and for making a deep trench structure in an electronic device. FIGS. 3-35 show the electronic device 100 of FIG. 1 at various stages of fabrication according to the method 200. The method 200 includes forming an STI structure that extends into a portion of a side of a semiconductor surface layer as well as and forming one or more deep trench structures through a portion of the STI structure, through the semiconductor surface layer 106, and into a buried layer 104. The method 200 begins with a starting substrate 102, such as a silicon wafer or a silicon on insulator wafer that includes majority carrier dopants of a first conductivity type (e.g., P in the illustrated example), or on a starting wafer that includes another semiconductor material.

The method 200 includes forming a buried layer at 202. FIG. 3 shows one example, in which an implantation process 300 is performed, such as a blanket implant or a selective implant using an implant mask (not shown). The implantation process 300 implants dopants of the second conductivity type (e.g., N in the illustrated example) into an exposed portion of the top side of the semiconductor substrate 102 to form the buried layer 104 in a portion of the semiconductor substrate 102.

At 204 in FIG. 2, the method 200 also includes forming a semiconductor surface layer on the semiconductor substrate. FIG. 4 shows one example, in which an epitaxial growth process 400 is performed with in-situ P-type dopants that grows the P-doped epitaxial silicon semiconductor surface layer 106 on the top side of the semiconductor substrate 102. The semiconductor surface layer 106 has a top side 107 as previously described.

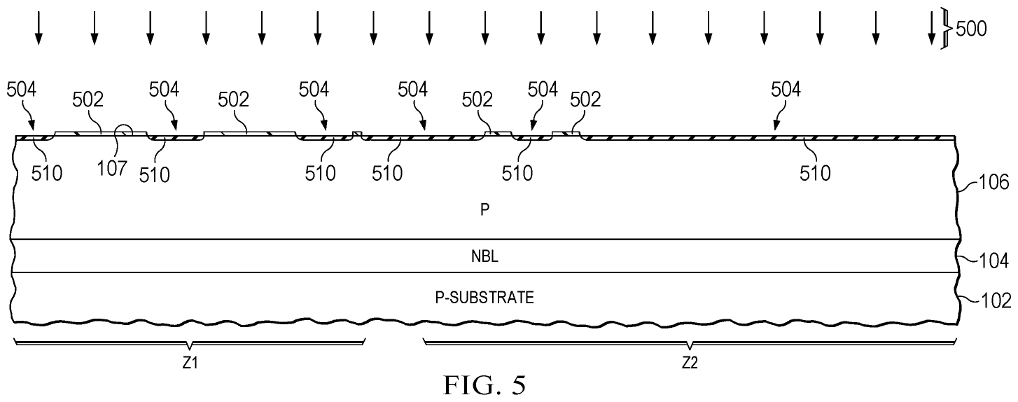

At 206 in FIG. 2, the method 200 also includes forming one or more shallow trench isolation structures, for example, by etching a trench and filling the trench with oxide or other suitable electrically isolating material. FIGS. 5-9 show one example, in which a trench etch process 500 is performed using a nitride or other suitable trench etch mask 502 in FIG. 5. The etch process 500 forms STI trenches 504 in select portions of the top side 107 of the semiconductor surface layer 106 that are not covered by the trench etch mask 502.

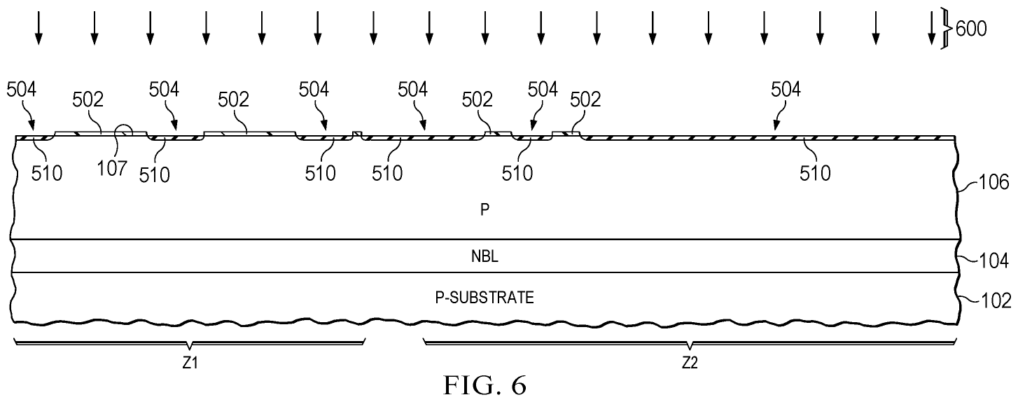

The STI structure formation at 206 in one example also includes oxidizing the exposed bottoms and sidewalls of the STI trenches 504. FIG. 6 shows one example, in which an oxidation process 600 is performed that exposes the processed wafer to an oxidizing environment with the trench etch mask 502 in place so that the exposed bottoms and sidewalls of the trench is 504 are oxidized.

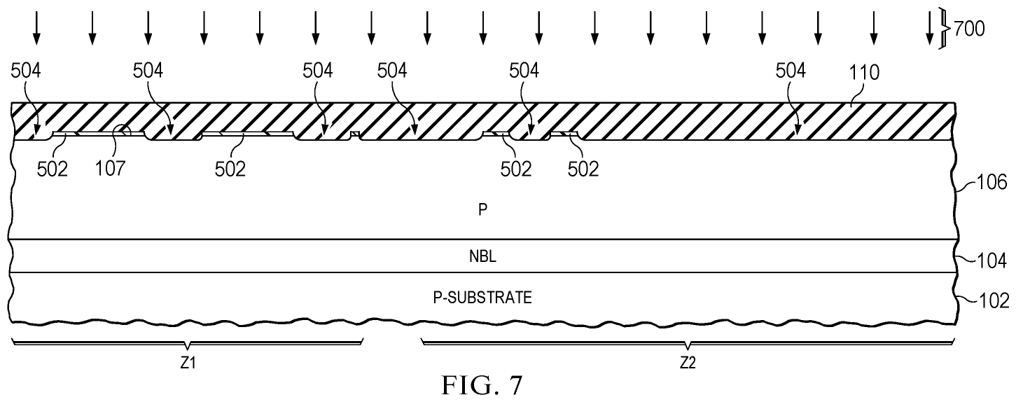

The STI processing at 206 also includes filling the trenches 504 with silicon dioxide or other suitable STI material. FIG. 7 shows one example, in which a deposition process 700 is performed that deposits silicon dioxide to fill the trenches 504, and the deposition is continued until the sides and tops of the trench etch mask 502 are covered with the oxide material.

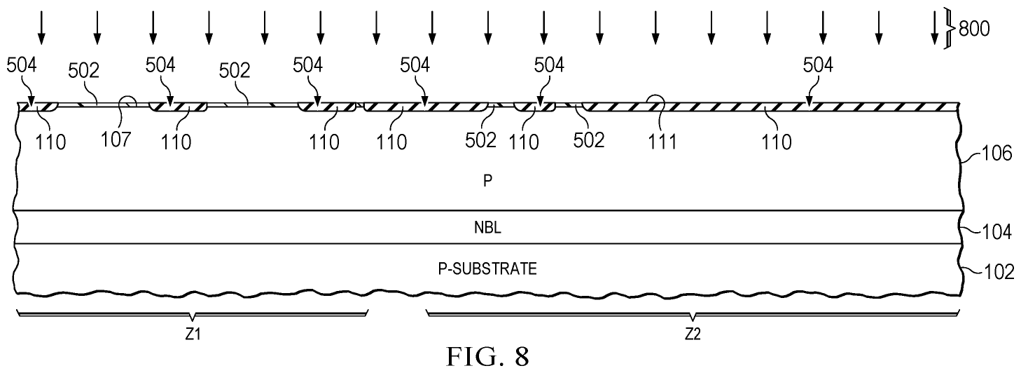

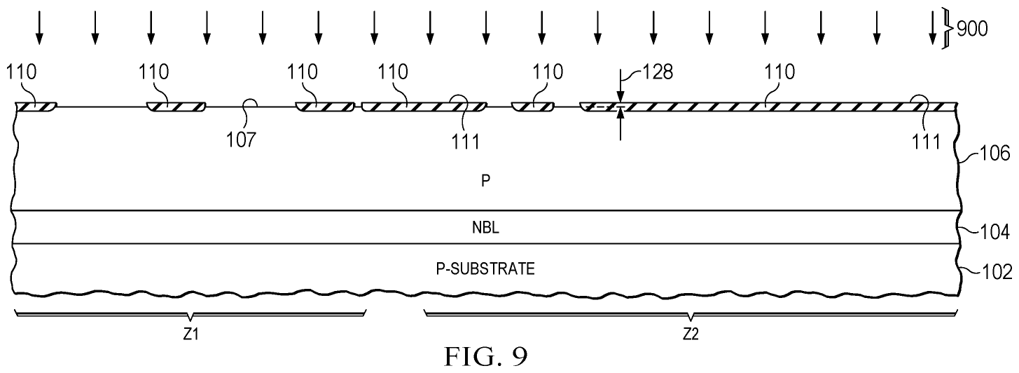

A planarization is then performed to planarize the top side of the processed wafer. FIG. 8 shows one example, in which a chemical mechanical polishing (CMP) process 800 is performed that removes portions of the deposited oxide material, leaving the finished STI structures 110 with generally planar top surfaces, and the process 800 exposes the STI trench etch mask 502. The method 200 continues at 208 with removing the STI trench etch mask 502. FIG. 9 shows an example, in which a stripping process 900 is performed that removes the STI trench etch mask 502 and leaves the patterned STI structures 110 having respective top surface 111 that extend above the top side 107 of the semiconductor surface layer 106 by the distance 128.

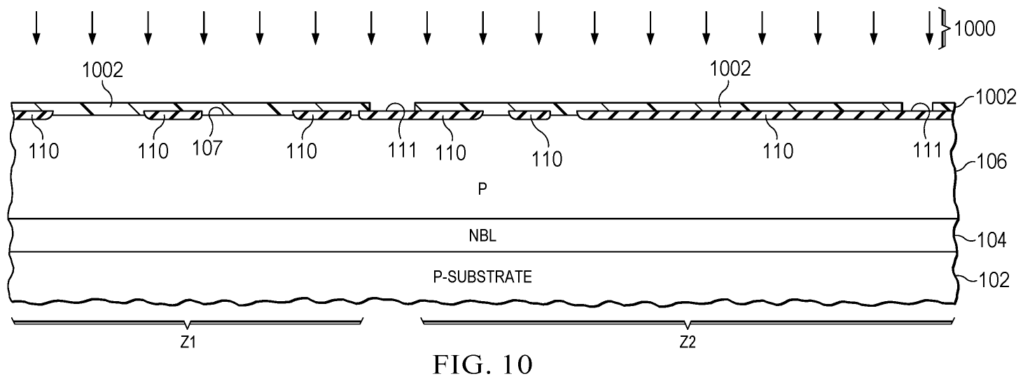

The method 200 continues at 210, 212, and 214 in FIG. 2 with forming one or more deep trench structures (e.g., trenches for the respective first and second deep trench structures 120 and 150 described above). FIGS. 10-17 show an example deep trench implementation that includes forming a dielectric trench etch mask at 210, etching through a portion of the STI structure 110 using the mask at 212, and etching through the semiconductor surface layer 106 and into the semiconductor substrate 102 at 214. In another implementation, the second etch at 214 forms one or more of the trenches partially into the semiconductor substrate 102 below the buried layer 104.

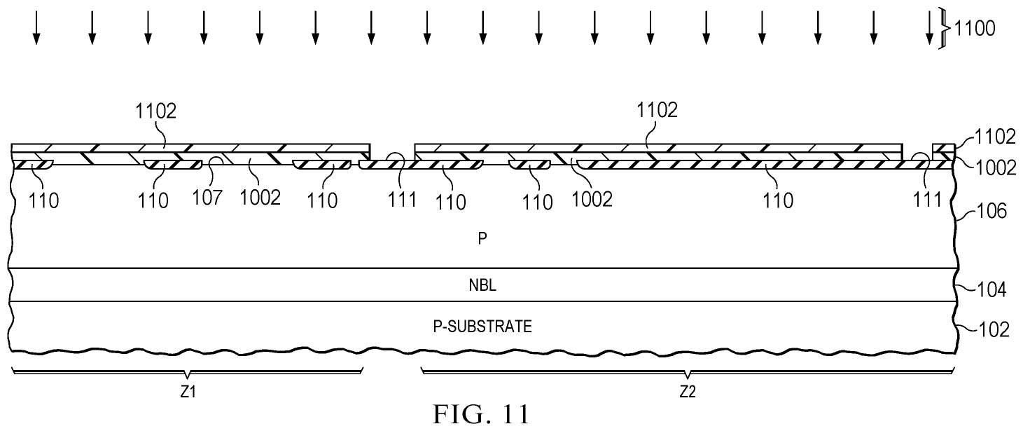

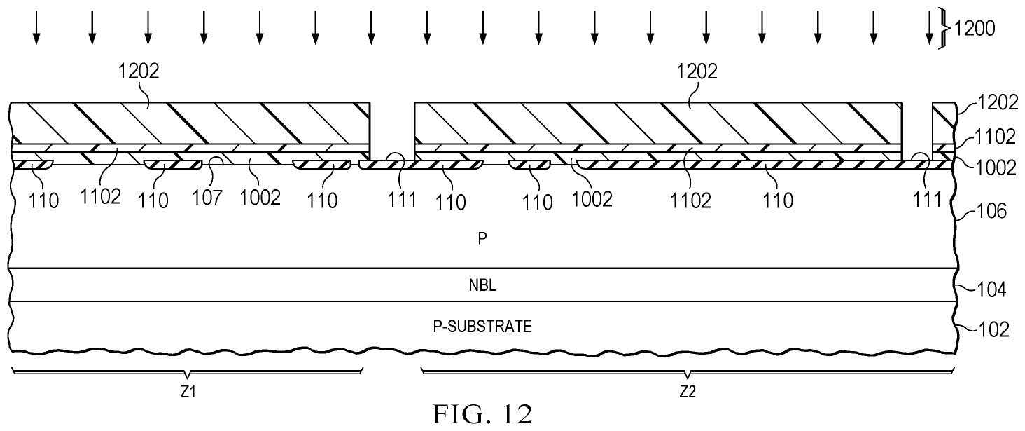

FIGS. 10-12 show an example of the trench etch mask formation at 210, in which a patterned multilayer etch mask is created. The nominal layer thicknesses and composition of the trench etch mask layers are adjustable depending on the depth of the isolation trench and vary within manufacturing tolerances. In other example, more or fewer layers are used in forming the trench etch mask at 210. In the illustrated implementation, a process 1000 is performed in FIG. 10 that deposits and patterns a silicon dioxide trench etch mask 1002 to expose first and second portions of the STI structure 110. In one example, the silicon dioxide layer 1002 has a thickness of 15 nm. In FIG. 11, a process 1100 is performed that deposits (e.g., by chemical vapor deposition) and patterns a silicon nitride trench etch mask 1102, for example, to a thickness of 200 nm on the trench etch mask 1002. In FIG. 12, a process 1200 is performed that deposits and patterns another silicon dioxide layer 1202, for example, to a thickness of 1.4 μm on the silicon nitride layer 1102 to complete the patterned multilayer dielectric trench etch mask 1002, 1102, 1202 with openings that expose first and second prospective deep trench locations along the top surface 111 of respective ones of the STI structures 110.

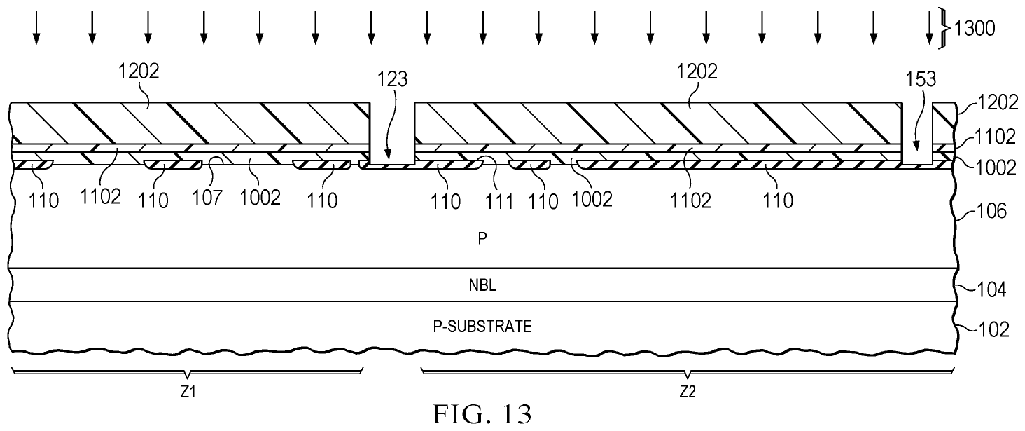

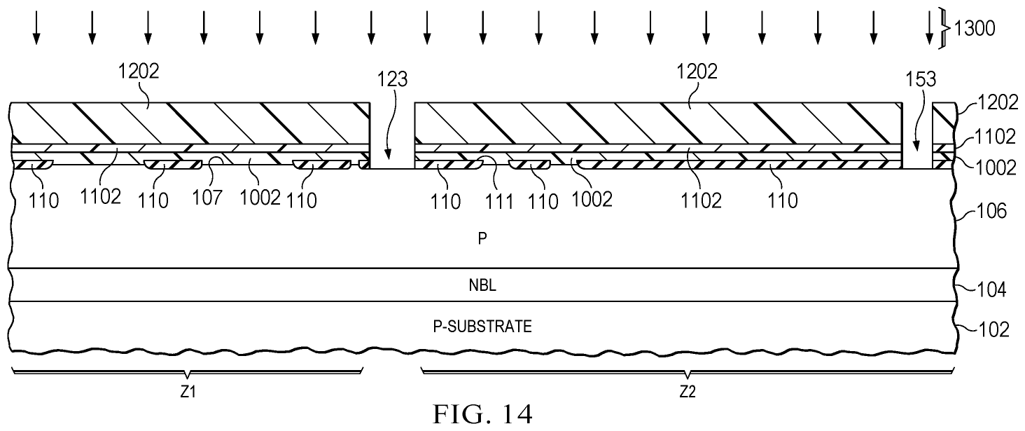

The method 200 continues at 212 in FIG. 2 with etching the exposed portions of the STI structure 110 to form initial portions of the deep trenches 123 and 153. FIGS. 13 and 14 show one example, in which a first etch process 1300 is performed using the trench etch mask 1002, 1102, 1202. FIG. 13 shows partial performance of the etch process 1300 forming the trenches 123 and 153 partially into portions of the respective STI structures 110 exposed by the trench etch mask 1002, 1102, 1202. FIG. 14 shows continued etching via the process 1300 to expose respective portions of the top side of the semiconductor surface layer 106 at the bottoms of the partially formed trenches 123 and 153. In one example, the first etch process 1300 is a fluorinated etch using carbon, fluorine, and hydrogen sources. In another example, the etch chemistry is carbon and fluorine only and no hydrogen. In one implementation, the first etch process 1300 is selective to the shallow trench isolation material using Ar/O₂/CF₄/CHF₃ and with or without one or more other fluorocarbons, and with or without N₂. In one example, the first etch process 1300 is performed at room temperature in a plasma etch reactor. In one implementation, an ash and clean operation is performed to strip off any remaining photo resist and clean the electronic device. In one example, the ash operation uses Ar/O₂/N₂/H₂/CF₄, either all or combinations thereof at a temperature of 100° C. or more. In one example, the clean operation is a dilute HF or industry standard cleaning chemistries in a single wafer tool or hood. In another implementation, the ash and clean operation is omitted.

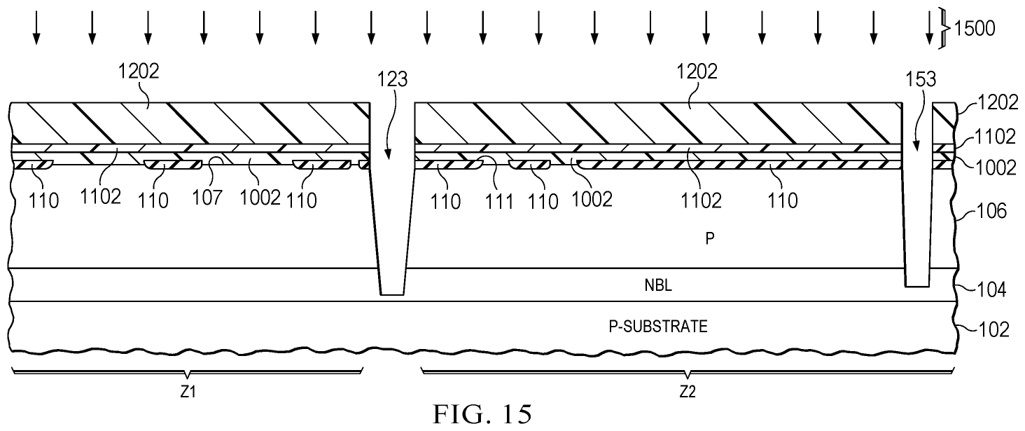

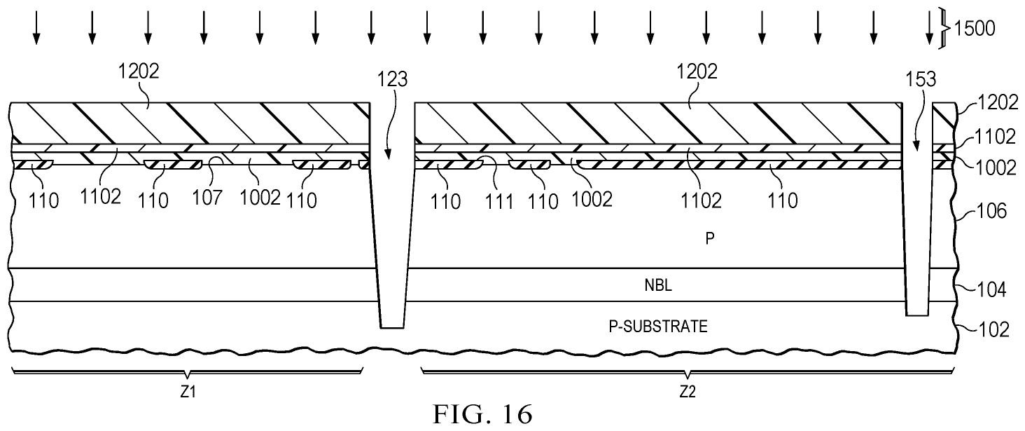

At 214 in FIG. 2, a second etch is performed using the trench etch mask 1002, 1102, 1202 to etch through the exposed portion of the semiconductor surface layer 106 and to expose first and second portions of the semiconductor substrate 102, either into or through the buried layer 104. In one implementation, the second etch process at 214 etches through the buried layer 104 and exposes a portion of the buried layer 104. FIGS. 15 and 16 show one example, in which a second etch process 1500 is performed using the trench etch mask 1002, 1102, 1202. FIG. 15 shows partial performance of the etch process 1500 that extends the trenches 123 and 153 into the respective portions of the buried layer 104. FIG. 16 shows continuation of the second etch process 1500 that etches through the remaining portion of the semiconductor surface layer 106 (e.g., and through the buried layer 104) and etches the trenches 123 and 153 into the semiconductor substrate 102 below the buried layer 104. In one example, the first etch process 1300 is performed in a first etching tool at 212, and the processed wafer is moved to a different etching tool for the second etch process 1500 at 214 in FIG. 2. In one example, the second etch process 1500 etches the trench 123 into the semiconductor surface layer 106 and into the semiconductor substrate 102 to a trench depth of 20 to 30 μm, such as about 26 μm, and stops in the semiconductor substrate 102 below the bottom of the buried layer 104 as shown in FIG. 16. In this or other examples, the narrower second trench 153 is etched by the process 1500 to a shallower trench depth due to the narrower opening in the trench etch mask 1002, one 1102, 1202. In one example, the second etch process 1500 uses a combination of SF₆, oxygen, argon, and HBr/N₂. In another implementation, the second etch process 1500 uses an Ar/SF₆/O₂/CF₄/HBr/N₂ etch chemistry. In other implementations, the second etch process 1500 uses a combination of all or some (e.g., two or more) of Ar/SF₆/O₂/CF₄/HBr/N₂. In one implementation, the second etch process 1500 is an anisotropic etch performed in a plasma reactor with source and bias radio frequency (RF) power.

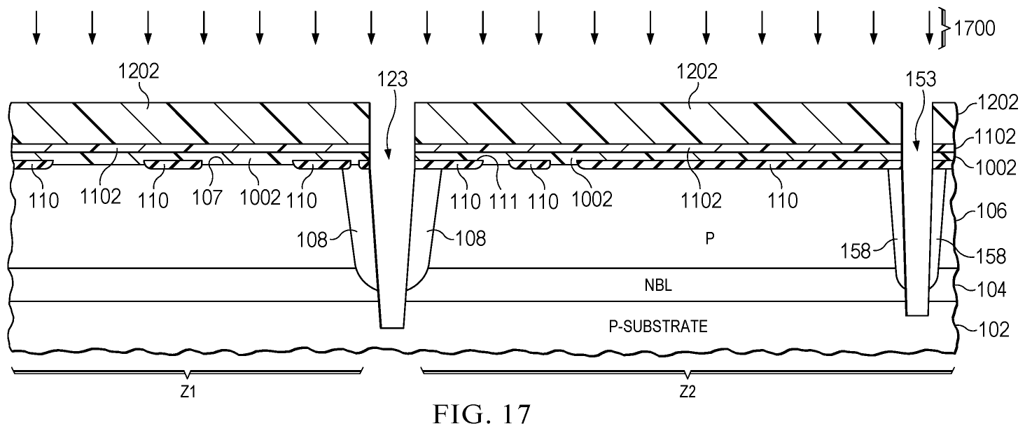

In the illustrated implementation, the method 200 continues at 216 with deep doped region implantation for the deep trenches 123 and 153. In another implementation, such as for a self-aligned deep doped regions 108 and 158 and isolation trenches 123 and 153, a portion of the trenches 123 and 153 are etched into a previously formed second deep implanted region using the second etch process 1500 to expose the blanket implanted buried layer, and the trench sidewalls are then implanted using traditional beam line implanters, after which the second etch process 1500 is resumed to etch the rest of the trenches 123 and 153. At 216 in FIG. 2, the method 200 forms the deep doped regions 108 and 158 that include majority carrier dopants of the second conductivity type (e.g., N). FIG. 17 shows one example, in which an implantation process 1700 is performed using the trench etch mask 1002, 1102, 1202. The implantation process 1700 implants dopants of the second conductivity type (e.g., N in the illustrated example) into exposed portions of the semiconductor surface layer 106 and the buried layer 104 to form the deep doped regions 108 and 158 extending from the semiconductor surface layer 106 and into to the buried layer 104.

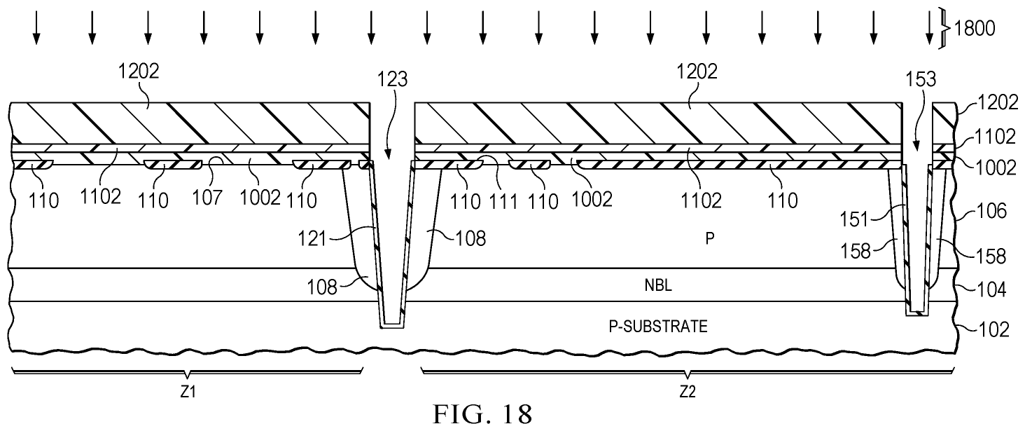

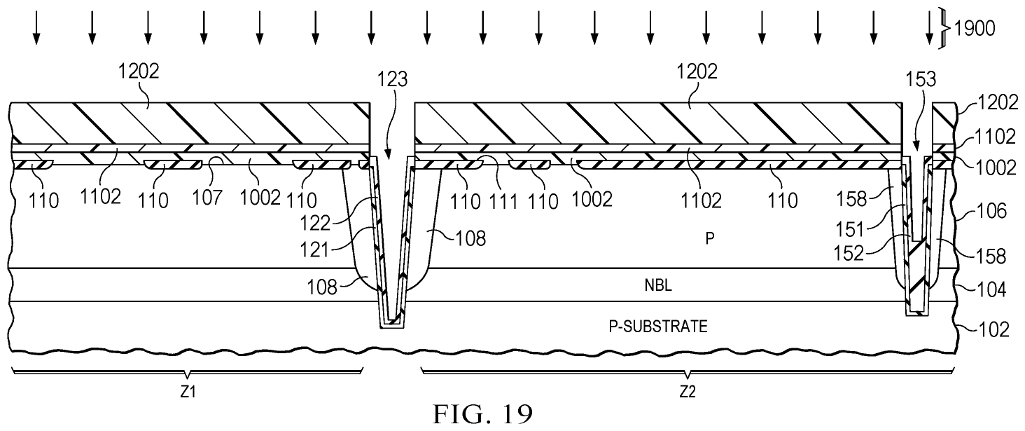

The method 200 continues at 218 in FIG. 2 with forming single or multi-layer trench liners in the trenches 123 and 153. The total thickness and composition of the trench liners are tailored according to a target breakdown voltage rating for the deep trench structures 120 and 150 in a given technology. In one example, the total thickness of the bilayer liners 121, 122 and 151, 152 is 500 to 600 nm. FIGS. 18 and 19 show one example that forms bilayer oxide trench liners 121, 122 and 151, 152 as shown in FIG. 1 above. The dielectric liners 121, 122 and 151, 152 in the illustrated example are formed along the sidewall of the respective trenches 123 and 153 from the semiconductor surface layer 106 to the semiconductor substrate 102. In another implementation, such as where a blanket implant was used to form the buried layer 104, the dielectric liners 121, 122 and 151, 152 extend to the buried layer 104. In another example where a blanket implant was used to form the buried layer 104, the dielectric liners 121, 122 and 151, 152 extend to the buried layer 104 and beyond into the underlying semiconductor substrate 102 below the buried layer 104. The nominal layer thicknesses and composition of the dielectric liners 121, 122 and 151, 152 are adjustable and vary within manufacturing tolerances. In other example, more or fewer layers are used in forming the trench liners for the trenches 123 and 153. In the illustrated example, the liner 152 in the narrower trench 153 fills the trench 153 to a higher level than the dielectric liner 122 in the wider trench 123.

FIG. 18 shows one example, in which a process 1800 is performed that forms the first dielectric liners 121 and 151 on the respective trench sidewalls. The process 1800 in one example includes thermal growth in a furnace with an oxidizing interior environment using an O₂ source stream at a temperature of about 1050° C. to deposit or grow the first dielectric liners 121 and 151 to a thickness of 100 to 400 nm.

In FIG. 19, a deposition process 1900 is performed that deposits the second dielectric liners 122 and 152 as second oxides on the respective first dielectric liners 121 and 151. In one implementation, the deposition process 1900 is a sub-atmospheric pressure chemical vapor deposition (SA-CVD) process, for example, using O₂ and/or ozone (O₃) as a source gas to help catalyze the reaction, at a pressure between 13,300 Pa and 80,000 Pa, and a process temperature of about 300 to 700° C. In one example, the process 1900 deposits the second dielectric liners 122 and 152 as conformal layers both inside the trenches 123 and 153 along the first dielectric liners 121 and 151, as well as outside the trenches 123 and 153 and on the trench etch mask 1002, 1102, 1202 (not shown in FIG. 19).

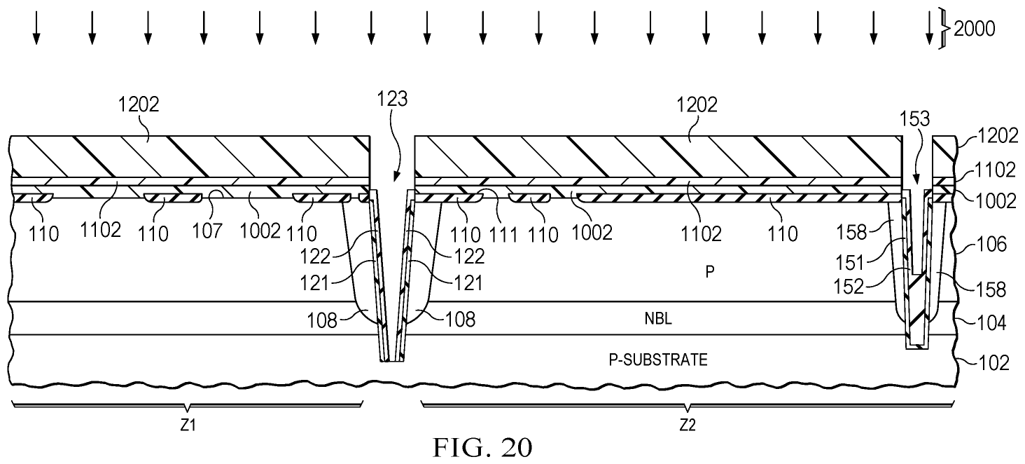

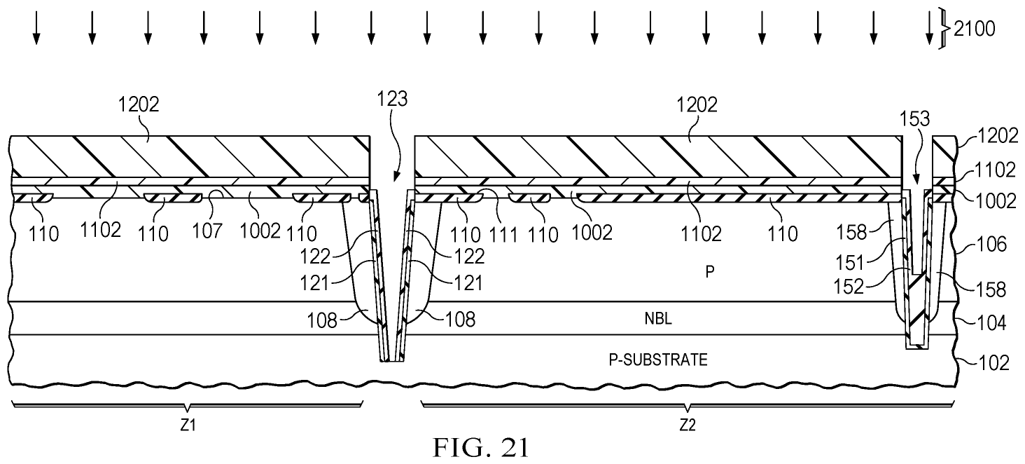

At 220 in FIG. 2, the method 200 continues with etching the dielectric liners 121 and 122 of the first trench 123. FIG. 20 shows one example, in which a trench liner etch process 2000 is performed, such as an anisotropic plasma dry etch that is self-aligned etch without any additional mask. In one implementation, the etch process 2000 uses all or a combination of Ar/CF₄/CH₂F₂/CHF₃/N₂/O₂, and/or another fluorocarbon source at room temperature in a plasma reactor with RF sources and bias power for anisotropy. The etch process 2000 removes the dielectric liners 121 and 122 from the bottom of the trench 123 and exposes a portion of the semiconductor substrate 102 in the first trench 123. In one example, the device is cleaned after the trench bottom etch at 220. FIG. 21 shows one example, in which a cleaning process 2100 is performed that cleans the bottom of the first trench 123. In one example, the cleaning process 2100 is a dilute HF or other low oxide loss cleaning operation performed in a single wafer processing tool or hood, such as SC1-SPOM, etc.

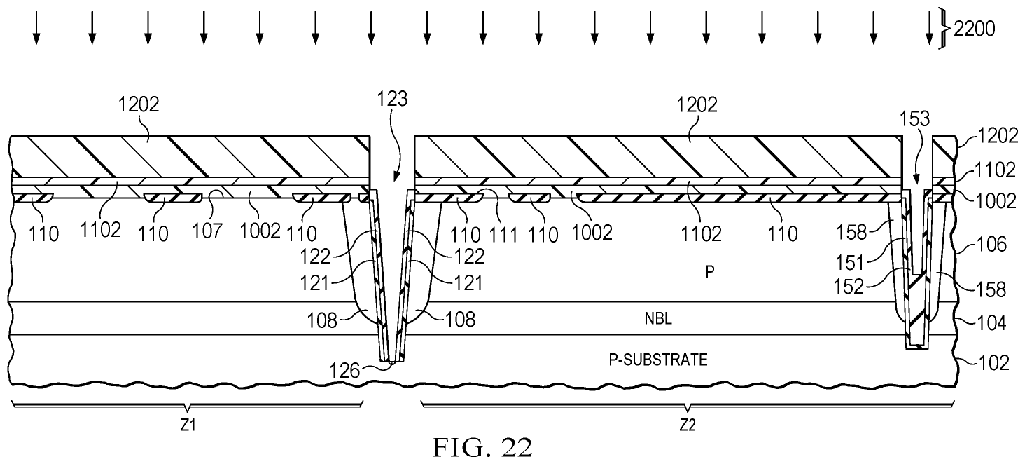

At 222 in FIG. 2, the method 200 continues with implanting the bottom of the first trench 123 with majority carrier dopants of a first conductivity type (e.g., P in the illustrated example). FIG. 22 shows one example, in which a trench bottom implantation process 2200 is performed that implants boron or other majority carrier dopants of the first conductivity type into the exposed portion of the semiconductor substrate 102 (e.g., to form the implanted contact 126 in FIG. 1). The trench bottom implantation process 2200 enhances conductivity and passivates any damage to the interface of the underlying material of the semiconductor substrate 102 or buried layer material resulting from the trench bottom etch process 2000. In one example, the trench bottom implantation process 2200 is performed using a beam line implantation tool for zero-degree implantation of boron dopants at an implantation energy of 60 keV to provide a majority carrier concentration of 5E14 cm⁻³ with four rotations of the wafer during implantation.

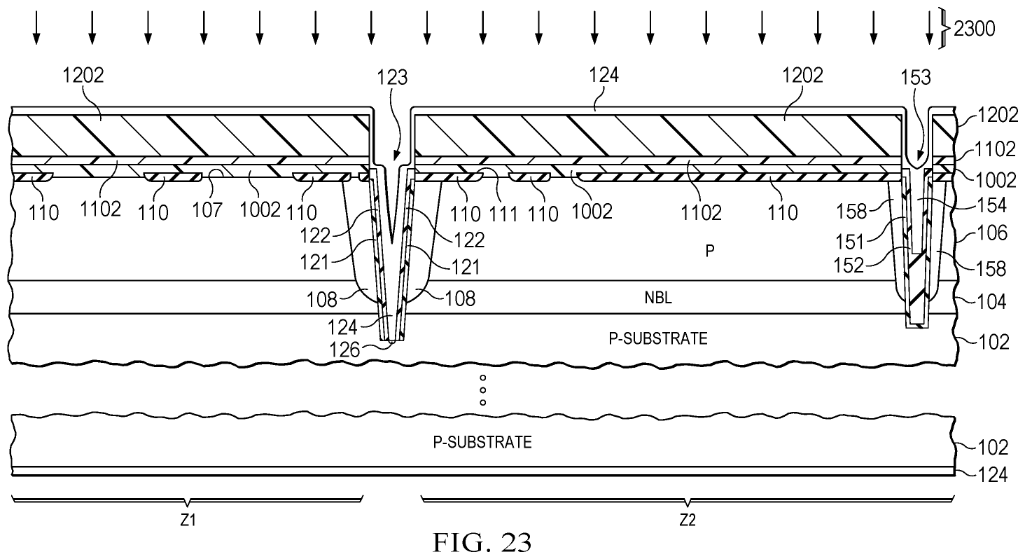

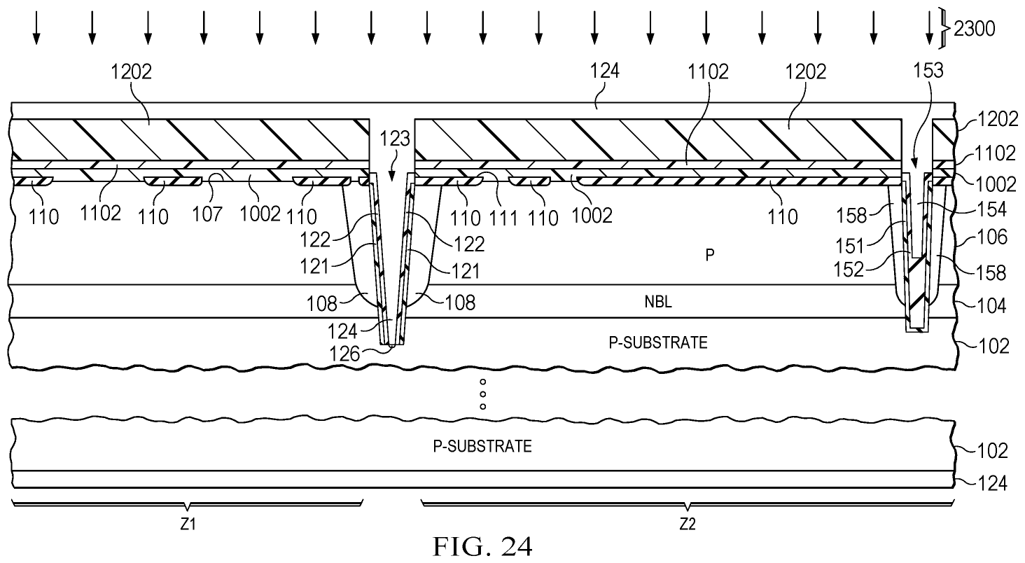

The method 200 in FIG. 2 also includes filling the trenches 123 and 153 with polysilicon 124, 154 at 224. FIGS. 23 and 24 show one example, in which a deposition process 2300 is performed that forms the polysilicon 124, 154 in the trenches 123 and 153 and fills the trenches 123 and 153 to and beyond the top side 107 of the semiconductor surface layer 106, including on the trench etch mask 1002, 1102, 1202. The process 2300 in one example includes epitaxial polysilicon growth with in-situ doping to form the doped polysilicon 124, 154 with majority carrier dopants of the first conductivity type (e.g., P in the illustrated example). FIG. 23 shows partial completion of the fill deposition process 2300 that conformally starts to fill the trenches 123 and 153 while conformally covering the device with deposited polysilicon 124, 154 outside the trenches 123 and 153 and on the wafer bottom. FIG. 24 shows completion of the process 2300 with the trenches 123 and 153 filled with polysilicon 124, 154.

In one example, the deposition process 2300 includes in-situ doped polysilicon fill using BCl₃ as a dopant source gas for boron with silane as the silicon source. In one implementation, the entire deposited polysilicon is doped in-situ. Another implementation deposits an in-situ doped thin layer and then deposits an undoped layer, followed by an anneal or high temperature drive step to diffuse dopants throughout the deposited polysilicon 124, 154. In one example, the polysilicon deposition process 2300 is performed in a furnace at a process temperature of 500 to 700° C. In another example, the process 2300 deposits completely undoped polysilicon 124, 154, followed by an implant with N-type or P-type dopants using a suitable implantation process. In another example, a deposition (e.g., epitaxial growth) is performed and a separate implantation provides majority carrier dopants of the first conductivity type into the deposited polysilicon 124, 154 in the trenches 123 and 153, followed by a thermal anneal to drive the implanted dopants into the polysilicon 124, 154 of the filled trenches 123 and 153. In the illustrated example, the process 2300 forms the polysilicon 124, 154 in the trenches 123, 153 along the respective dielectric liners 121, 122 and 151, 152 and the polysilicon 124, 154 also extends over the trench etch mask 1002, 1102, 1202 that remains on the STI structures 110.

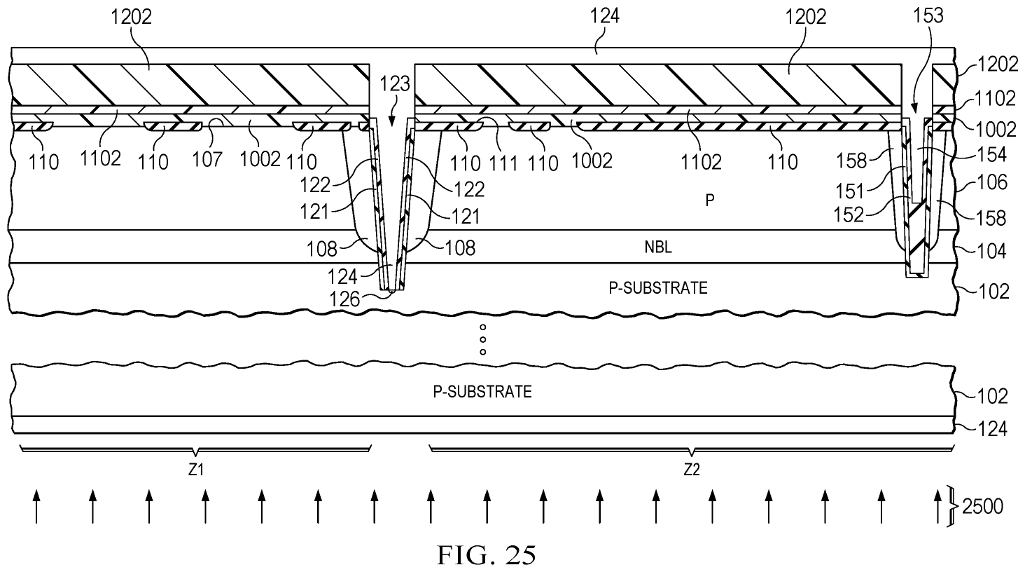

The method 200 continues at 226 in FIG. 2 with removing the deposited polysilicon from the wafer backside (e.g., from the bottom of the semiconductor substrate 102). FIG. 25 shows one example, in which a stripping process 2500 is performed that removes the polysilicon 124 from the back side of the semiconductor substrate 102. In one implementation, the back side poly strip process 2500 includes exposing the back side of the semiconductor substrate 102 to HF/nitric acid to provide high selectivity to SiO₂ and SiN using a wafer clean tool, such as SEZ, etc.

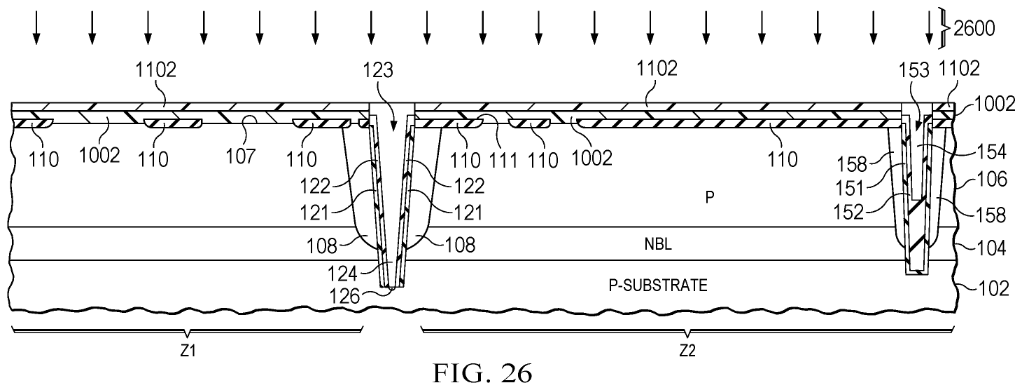

At 228 in FIG. 2, the method 200 also includes planarizing the front side of the wafer (e.g., the top side in the illustrated orientation). FIG. 26 shows one example, in which a chemical mechanical polishing (CMP) process 2600 is performed that planarizes the top side and sets the height of the top surfaces 125, 155 of the DTI structures and of the polysilicon 124, 154 in the respective trenches 123 and 153. In one example, the CMP process 2600 stops on or slightly above the trench etch mask 1102 of the multilayer trench etch mask. In one implementation, the CMP process 2600 is performed in a CMP tool using a process slurry, for example, a ceria slurry that has good selectivity to nitride, in which the polysilicon 124, 154 is polished with an endpoint to stop on the silicon dioxide trench etch mask 1202, after which the silicon dioxide is polished stopping on the silicon nitride trench etch mask 1102. In one implementation, a further cleaning operation (not shown) is performed at 228, for example, using a non-HF solution to mitigate surface particle defects.

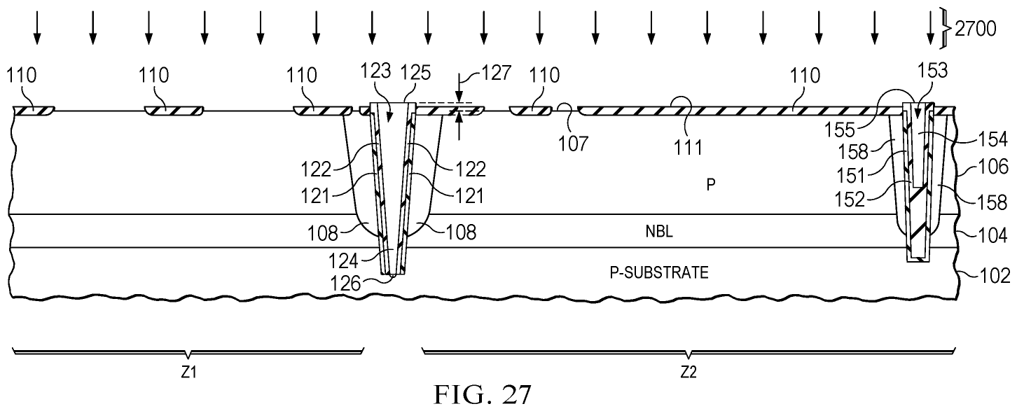

The method 200 continues at 230 in FIG. 2 with stripping our other process to remove the remaining trench etch mask remnants. FIG. 27 shows one example, in which a nitride strip process 2700 is performed that removes any remaining portions of the trench etch masks 1002 and 1102. In one example, the nitride strip process 2700 includes a hot phosphoric acid clean to etch silicon nitride.

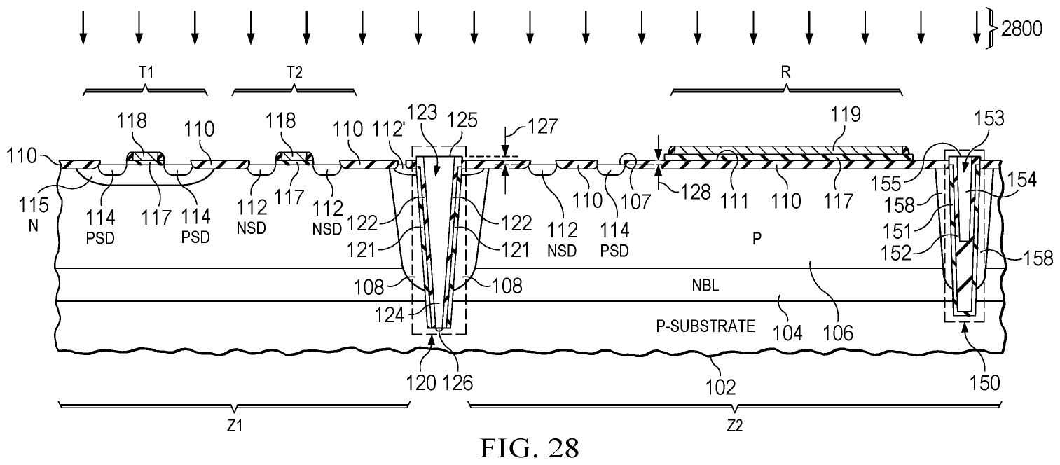

The method 200 also includes transistor fabrication at 232. FIG. 28 shows one example, in which processing 2800 is performed that forms the transistors T1 and T2 and the resistor R, for example, including gate polysilicon deposition and patterning, and various implantations (not shown) to form all or parts of various circuit components, such as transistors, polysilicon capacitors and resistors, diodes, etc.

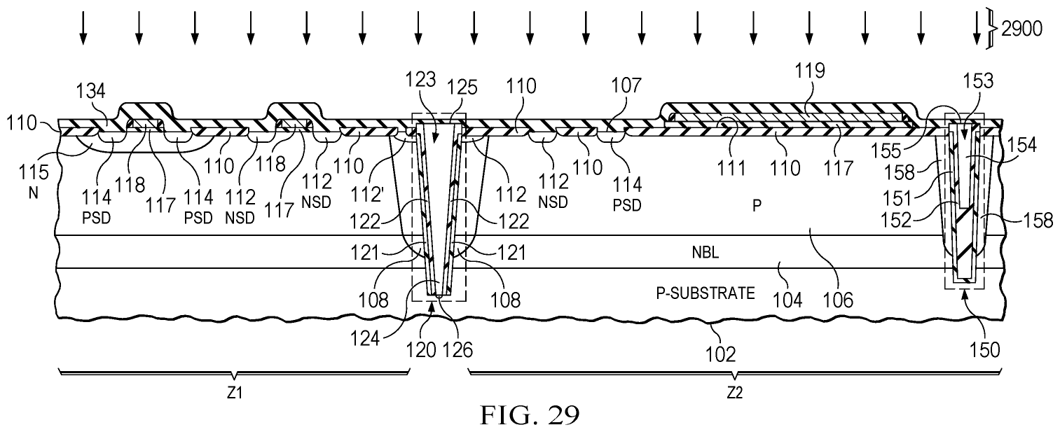

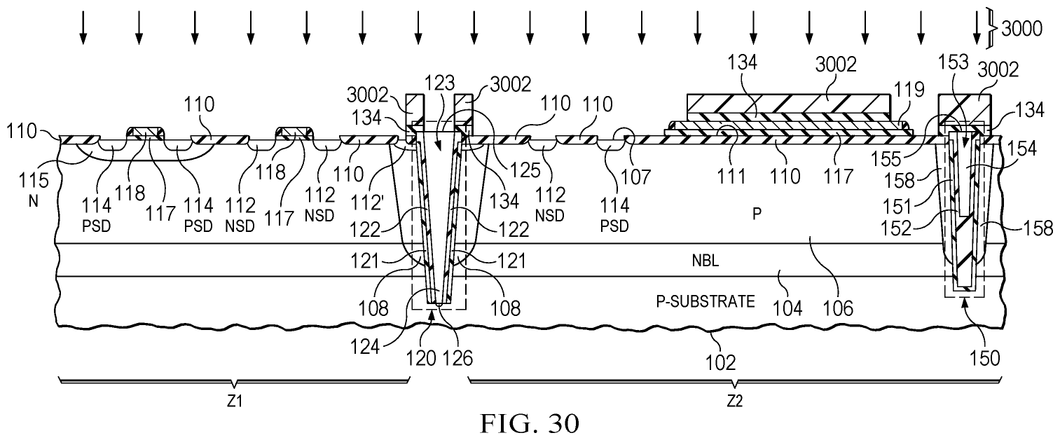

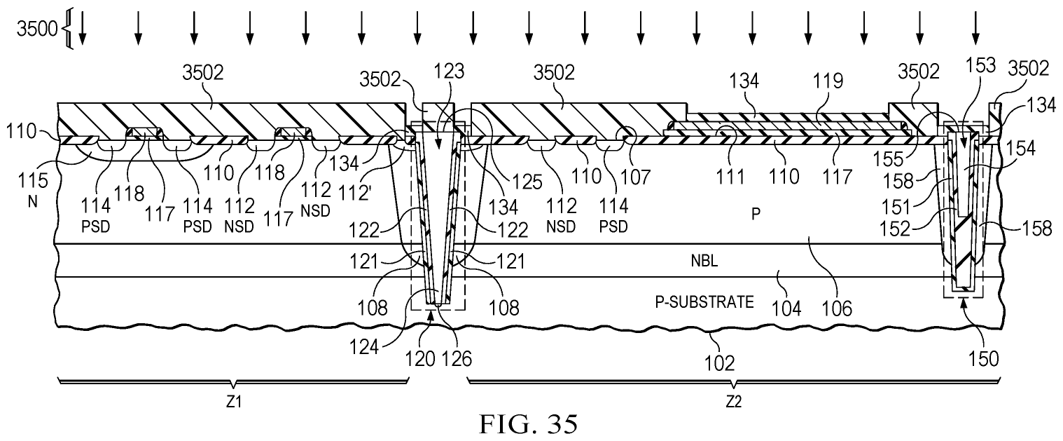

At 234, the method 200 also includes forming the silicide blocking layer 134 on a first portion of the first deep trench structure 120 and on the top side of the second deep trench structure 150. FIGS. 29 and 30 show one example, in which a deposition process 2900 is performed in FIG. 29 that deposits a silicon oxynitride layer 2910 on the STI structure 110 and the deep trench structure 120 to any suitable thickness and stoichiometry. In this example, an etch process 3000 is performed in FIG. 30 using a mask 3002 that covers the deposited silicon oxynitride layer 2910 above a first portion of the first deep trench structure 120 (e.g., above the dielectric liners 121 and 122), and the mask 2002 covers the silicon oxynitride layer 2910 above the second deep trench structure 120 entirely. The etch process 3000 etches the silicon oxynitride layer 2910. FIG. 35 shows an alternate implementation using LOCOS to form a silicon dioxide silicide blocking layer 134.

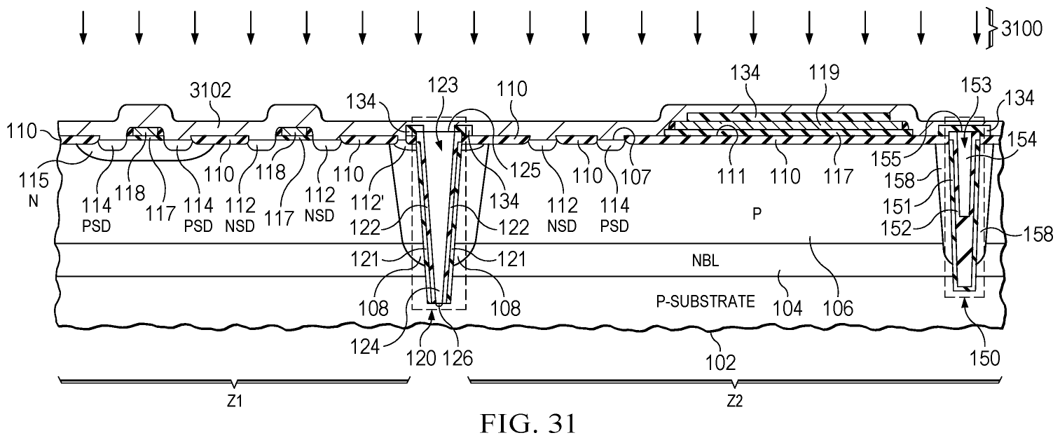

In the example using the silicide blocking layer 134, the method 200 continues at 236 in FIG. 2 with forming metal silicide 131 on a second portion of the first deep trench isolation structure 120. FIG. 31 shows one example, in which a silicidable metal is formed by a deposition process 3100 is performed that deposits a silicidable metal layer 3102 over the top surfaces of any uncovered polysilicon or silicon of the semiconductor surface layer 106, and on the tops of the STI structure 110 and deep trench structures 120 and 150, as well as on the silicide blocking layer 134. In one implementation, the silicidable metal layer 3102 is or includes titanium, cobalt, tungsten, nickel-platinum, and/or nickel. Other silicidable metals can be used in other implementations. In the illustrated example, moreover, the deposition process 3100 deposits the silicidable metal layer 3102 on the polysilicon gate electrodes 118 and the implanted source/drain regions implanted 112 and 114 on or in the semiconductor surface layer 106 for concurrently forming silicide contacts for the transistors T1 and T2, as well as on the uncovered ends of the polysilicon resistor R for forming silicide contacts thereat.

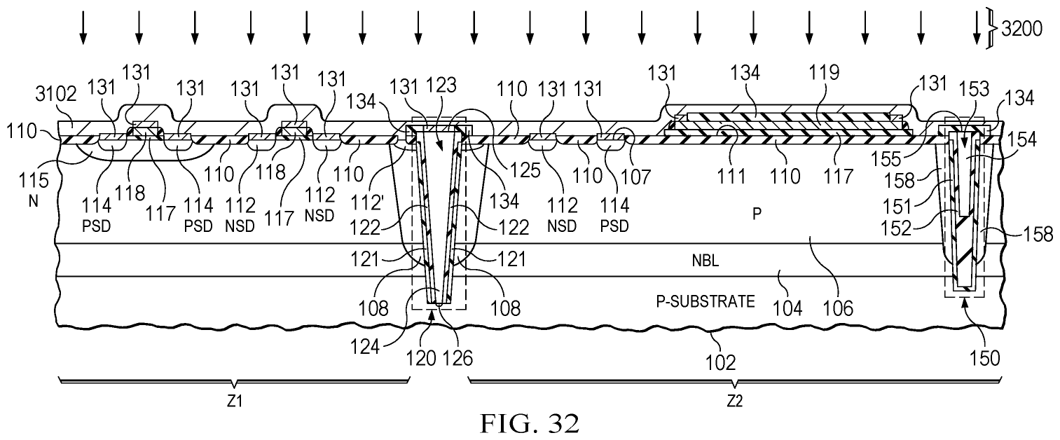

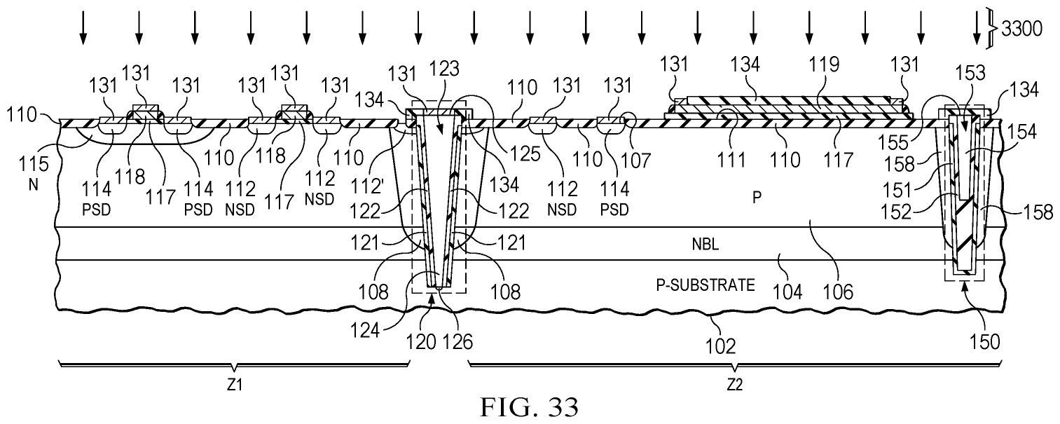

A first anneal is performed at 236 in one example to form the metal silicide 131 by silicidation of the silicon and polysilicon with the silicidable metal layer 3102. FIG. 32 shows one example, in which a thermal anneal process 3200 is performed that concurrently forms metal silicide 131 for the transistor source/drain contacts by silicidation of silicon of the source/drain implanted regions 112 and 114 of the semiconductor surface layer 106 with the silicidable metal layer 3102, and also forms the metal silicide 131 for the transistor gate electrodes 118, the first DTI structure contacts, and for the resistor R by silicidation of the polysilicon 119 with the silicidable metal layer 3102. In one example, the formed metal silicide 131 are or include nickel silicide, nickel-platinum silicide, cobalt silicide, titanium silicide, tungsten silicide, or another metal silicide. The silicidation processing at 236 in this example also includes removing substantially all unreacted metal 3102 from the metal silicide 131 and other structures. FIG. 33 shows one example, in which a process 3300 is performed that removes substantially all unreacted silicidable metal 3102.

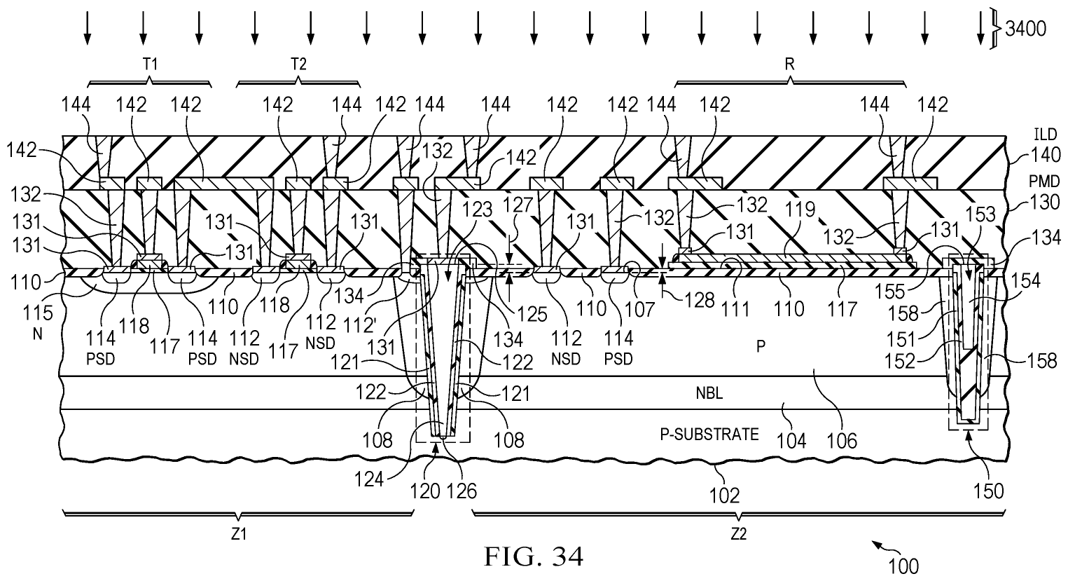

The processing at 236 in FIG. 2 also includes metallization processing, including forming the pre-metal dielectric (PMD) layer 130 on the silicide blocking layers 134 of the respective deep trench structures 120 and 150 and the metal silicide 131, forming the metal contact 132 that extends through the PMD layer 130 and contacts the metal silicide 131 on the second portion of the first deep trench structure 120, and the other conductive metal contacts (e.g., tungsten) shown in FIG. 34. The metallization processing 3400 at 236 in FIG. 2 also includes forming one or more ILD dielectric layers and associated metal routing trace features and vias to create a single or multilayer metallization structure as shown in FIGS. 34 and 1, for example, where the metallization structure couples the metal silicide 131 and the terminals of the passive circuit components to one or more respective circuits and provides electrical coupling of the transistor source, drain, and gate terminals. Also, at 236, the processed wafer undergoes wafer probe testing and individual semiconductor dies are separated or singulated from the wafer and packaged at 236 in FIG. 2, where FIG. 1A above shows an example of a resulting packaged electronic device 100 with a molded package structure and conductive leads.

FIG. 35 shows an alternate implementation of the method 200, in which the silicide blocking layer 134 is formed by thermally growing silicon dioxide using a LOCOS process 3500. This example includes forming a mask 3502 that exposes the first portion of the deep trench structure 120 and performing a thermal oxidation process 3500 that oxidizes polysilicon 124 of the first portion of the deep trench structure 120 to form the silicide blocking layer 134 that is or includes silicon dioxide in the areas exposed by the mask 3502, after which the mask 3502 is removed. In this example, the processed wafer then undergoes silicidation, metallization, wafer probe testing, die separation and packaging at 236 as described above.

Modifications are possible in the described examples, and other implementations are possible, within the scope of the claims.

What is claimed is:

1. An electronic device, comprising:
a semiconductor substrate and a semiconductor surface layer having a first conductivity type, the semiconductor surface layer over the semiconductor substrate and having a top surface;
a buried layer having an opposite second conductivity type between the semiconductor surface layer and the semiconductor substrate;
a dielectric isolation layer that extends over and into the semiconductor surface layer;
a deep trench structure that extends through the dielectric isolation layer into the semiconductor surface layer; and
a silicide blocking layer on a top surface of the deep trench structure.

2. The electronic device of claim 1, wherein the top surface is higher than a top side of the semiconductor surface layer.

3. The electronic device of claim 1, wherein the silicide blocking layer extends over a polysilicon core of the deep trench structure.

4. The electronic device of claim 1, wherein the deep trench structure extends through the buried layer and touches the semiconductor substrate.

5. The electronic device of claim 4, wherein the deep trench structure is a first deep trench structure and further comprising a second deep trench structure that extends through the dielectric isolation layer and into the buried layer,
wherein the first deep trench structure includes a first polysilicon core that touches the semiconductor substrate and the second deep trench structure includes a second polysilicon core that is conductively isolated from the semiconductor substrate.

6. The electronic device of claim 1, wherein the deep trench structure is a first deep trench structure having a first polysilicon core and the silicide blocking layer is a first silicide blocking layer, and further comprising a second deep trench structure having a second polysilicon core and a second silicide blocking layer, wherein:
a metal silicide layer covers the first polysilicon core and the second silicide blocking layer covers the second polysilicon core.

7. The electronic device of claim 1, wherein the silicide blocking layer includes nitrogen.

8. The electronic device of claim 1, wherein:
the deep trench structure includes a trench through the semiconductor surface layer and into the buried layer, a dielectric liner on a sidewall of the trench from the semiconductor surface layer to the buried layer, and polysilicon that extends on the dielectric liner and fills the trench; and
the silicide blocking layer covers the dielectric liner of the deep trench structure and does not cover a portion of the polysilicon of the deep trench structure.

9. The electronic device of claim 8, further comprising:
metal silicide on the portion of the polysilicon of the deep trench structure; and
a metal contact that contacts the metal silicide on the portion of the poly silicon of the deep trench structure.

10. The electronic device of claim 1, wherein:
the deep trench structure includes a trench through the semiconductor surface layer and into the buried layer, a dielectric liner on a sidewall of the trench from the semiconductor surface layer to the buried layer, and polysilicon that extends on the dielectric liner and fills the trench; and
the silicide blocking layer covers the dielectric liner of the deep trench structure and covers the polysilicon of the deep trench structure.

11. The electronic device of claim 1, wherein the dielectric isolation layer is a shallow trench isolation (STI) layer.

12. The electronic device of claim 1, wherein the silicide blocking layer includes a nitrogen-containing dielectric material.

13. An integrated circuit, comprising:
a semiconductor surface layer over a semiconductor substrate;
a dielectric isolation structure that extends into the semiconductor surface layer;
a trench through the dielectric isolation structure and within the semiconductor surface layer;
a first dielectric liner within the trench located directly on the semiconductor surface layer;
a second dielectric liner within the trench located directly on the first dielectric liner; and
a silicide blocking layer located over and touching the dielectric isolation structure and the second dielectric liner.

14. The integrated circuit of claim 13, wherein the second dielectric liner extends above a top side of the semiconductor surface layer, and the silicide blocking layer touches a top surface and a side surface of the second dielectric liner.

15. The integrated circuit of claim 13, wherein the dielectric isolation structure is a shallow trench isolation (STI) structure.

16. A method of fabricating an electronic device, the method comprising:
forming a dielectric isolation layer that extends over a semiconductor surface layer;
forming a deep trench structure through the dielectric isolation layer, through the semiconductor surface layer, and into a buried layer;
forming a silicide blocking layer on a first portion of the deep trench structure; and
forming metal silicide on a second portion of the deep trench structure.

17. The method of claim 16, wherein the deep trench structure is a first deep trench structure, and further comprising:
forming a second deep trench structure through the dielectric isolation layer, through the semiconductor surface layer, and into the buried layer;
forming a second silicide blocking layer on the second deep trench structure;
forming a pre-metal dielectric layer on the silicide blocking layer, the second silicide blocking layer, and the metal silicide; and
forming a metal contact that extends through the pre-metal dielectric layer and contacts the metal silicide on the second portion of the first deep trench structure.

18. The method of claim 16, wherein forming the deep trench structure includes:
forming a trench through the dielectric isolation layer, through the semiconductor surface layer, and into the buried layer;
forming a dielectric liner along a sidewall of the trench from the dielectric isolation layer to the buried layer; and
filling the trench with poly silicon.

19. The method of claim 16, wherein forming the silicide blocking layer includes:
performing a deposition process that deposits a nitrogen-containing layer on the dielectric isolation layer and the deep trench structure; and
performing an etch process using a mask that covers the first portion of the deep trench structure to etch the nitrogen-containing layer.

20. The method of claim 16, wherein forming the silicide blocking layer includes:
forming a mask that exposes the first portion of the deep trench structure; and
performing a thermal oxidation process that oxidizes polysilicon of the first portion of the deep trench structure to form the silicide blocking layer.
